(19) United States
(12) Patent Application Publication
(10) Pub. No.: US 2018/0033619 A1
(43) Pub. Date: Feb. 1, 2018

(54) PERFORMING DECOUPLED PLASMA FLUORINATION TO REDUCE INTERFACIAL DEFECTS IN FILM STACK

(71) Applicant: Applied Materials, Inc., Santa Clara, CA (US)

(72) Inventors: Wei LIU, San Jose, CA (US); Linlin WANG, Fremont, CA (US)

(21) Appl. No.: 15/417,473

(22) Filed: Jan. 27, 2017

Related U.S. Application Data
(60) Provisional application No. 62/368,531, filed on Jul. 29, 2016.

(51) Int. Cl. H01L 21/02; H01L 21/28

(52) U.S. Cl. CPC H01L 21/02321; H01L 21/0234; H01L 21/28185; H01L 29/517

(57) ABSTRACT

Embodiments of the present disclosure generally relate to methods for forming a dielectric material on a substrate, and more specifically, to methods for forming a high-k dielectric layer in an electronic device. In one embodiment, the method includes depositing a high-k dielectric layer on a substrate and fluorinating the deposited high-k dielectric layer. The fluorinating the high-k dielectric layer includes exposing the high-k dielectric layer to a fluorine containing plasma at temperature between about 200 degrees Celsius and about 550 degrees Celsius. At this temperature range, the fluorine radicals form fluorine bonds at the interface between the high-k dielectric layer and the substrate without etching any materials.

### CROSS-REFERENCE TO RELATED APPLICATIONS

This application claims priority to U.S. Provisional Patent Application Ser. No. 62/368,531, filed on Jul. 29, 2016, which herein is incorporated by reference.

### BACKGROUND

### Field

Embodiments of the present disclosure generally relate to methods for forming a dielectric material on a substrate, and more specifically, to methods for forming a high-k dielectric layer in an electronic device.

### Description of the Related Art

Integrated circuits may include more than one million micro-electronic field effect transistors (e.g., complementary metal-oxide-semiconductor (CMOS) field effect transistors) that are formed on a substrate (e.g., semiconductor substrate) and cooperate to perform various functions within the circuit. A CMOS transistor includes a gate structure disposed between source and drain regions that are formed in the substrate. The gate structure generally includes a gate electrode and a gate dielectric. The gate electrode is disposed over the gate dielectric to control a flow of charge carriers in a channel region formed between the drain and source regions beneath the gate dielectric. Typically, dielectric materials, such as SiO₂, may be used as the gate dielectric. Recently, the gate dielectric may be formed from a material having a dielectric constant greater than 4.0, or high-k dielectric material, in order to increase the speed of the transistor. However, dangling bonds, or defects, may be formed at the interfaces between the high-k dielectric material and the adjacent layers. The defects at the interfaces can lead to significant threshold voltage shift and device performance degradation.

Therefore, there is a need for a process to form dielectric materials, such as high-k dielectric materials.

### SUMMARY

Embodiments of the present disclosure generally relate to methods for forming a dielectric material on a substrate, and more specifically, to methods for forming a high-k dielectric layer in an electronic device. In one embodiment, a method includes exposing a substrate having a high-k dielectric layer to a fluorine containing plasma, and a temperature of the substrate is between about 200 degrees Celsius and about 550 degrees Celsius during the exposure to the fluorine containing plasma.

In another embodiment, a method includes forming a fluorinated high-k dielectric layer by fluorinating a high-k dielectric layer on a substrate. The fluorinating the high-k dielectric layer includes exposing the high-k dielectric layer to a fluorine containing plasma at a first temperature less than about 200 degrees Celsius, and increasing the first temperature to a second temperature between about 300 degrees Celsius and about 550 degrees Celsius.

In another embodiment, a method includes forming a fluorinated high-k dielectric layer by fluorinating a high-k dielectric layer on a substrate. The fluorinating the high-k dielectric layer includes exposing the high-k dielectric layer to a fluorine containing gas, wherein a temperature of the substrate is between about 650 degrees Celsius and about 700 degrees Celsius during the exposure to the fluorine containing gas, wherein the fluorine containing gas is introduced into the processing chamber at a temperature less than about 100 degrees Celsius.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates operations of a method according to one embodiment disclosed herein.

FIG. 2 illustrates operations of a method according to another embodiment disclosed herein.

FIG. 3 is a schematic diagram of a plasma chamber according to one embodiment disclosed herein.

FIG. 4 illustrates operations of a method according to another embodiment disclosed herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to methods for forming a dielectric material on a substrate, and more specifically, to methods for forming a high-k dielectric layer in an electronic device. In one embodiment, the method includes depositing a high-k dielectric layer on a substrate and fluorinating the deposited high-k dielectric layer. The fluorinating the high-k dielectric layer includes exposing the high-k dielectric layer to a fluorine containing plasma at temperature between about 200 degrees Celsius and about 550 degrees Celsius. At this temperature range, the fluorine radicals form fluorine bonds at the interface between the high-k dielectric layer and the substrate without etching any materials.

As used herein, the term “high-k dielectric” generally refers to a variety of compositions that are homogenous, heterogeneous, graded and/or multiple layered stacks or laminates. In one embodiment, the high-k dielectric has a dielectric constant greater than 3.9, such as greater than 6, greater than 8, or greater than 10. The high-k dielectric may include combinations of hafnium, zirconium, titanium, tantalum, lanthanum, aluminum, silicon, oxygen and/or nitrogen. High-k dielectric materials may include silicon oxynitrides (SiOₓN_{y}), hafnium containing materials, such as hafnium oxides (HfOₓ including HfO₂), hafnium silicates (HfSiₓO_{y} including HfSiO₄), hafnium, silicon oxynitrides (HfSiₓO_{y}N_{z}), hafnium oxynitrides (HfOₓN_{y}), hafnium aluminates (HfAlₓO_{y}), hafnium aluminum silicates (HfAlₓSi_{y}O_{z}), hafnium aluminum silicon oxynitrides (HfAl_{w}SiₓO_{y}N_{z}), hafnium lanthanum oxides (HfLaₓO_{y}), zirconium containing materials, such as zirconium oxides (ZrOₓ including ZrO₂), zirconium silicates (ZrSiₓO_{y} including ZrSiO₄), zirconium silicon oxynitrides (ZrSiₓO_{y}N_{z}), zirconium oxynitrides (ZrOₓN_{y}), zirconium aluminates (ZrAlₓO_{y}), zirconium aluminum silicates (ZrAlₓSi_{y}O_{z}), zirconium aluminum silicon oxynitrides (ZrAl_{w}SiₓO_{y}N_{z}), zirconium lanthanum oxides (ZrLaₓO_{y}), other aluminum-containing materials or lanthanum-containing materials, such as aluminum oxides (Al₂O₃ or AlOₓ), aluminum oxynitrides (AlOₓN_{y}), aluminum silicates (AlSiₓO_{y}), aluminum silicon oxynitrides (AlSiₓO_{y}N_{z}), lanthanum aluminum oxides (LaAlₓO_{y}), lanthanum oxides (LaOₓ or La₂O₃), other suitable materials, composites thereof, and combinations thereof. Other high-k dielectric materials useful for dielectric layers may include titanium oxides (TiOₓ or TiO₂), titanium oxynitrides (TiOₓN_{y}), tantalum oxides (TaOₓ or Ta₂O₅) and tantalum oxynitrides (TaOₓN_{y}). Laminate films that are useful dielectric materials for high-k dielectric layers include HfO₂/Al₂O₃, HfO₂/SiO₂, La₂O₃/Al₂O₃ and HfO₂/SiO₂/Al₂O₃.

As used herein, the term “substrate” generally refers to any substrate or material surface formed on a substrate upon which film processing is performed. For example, a substrate on which processing can be performed includes materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates may have various dimensions, such as 200 mm, 300 mm, or 450 mm diameter wafers, as well as, rectangular or square panes.

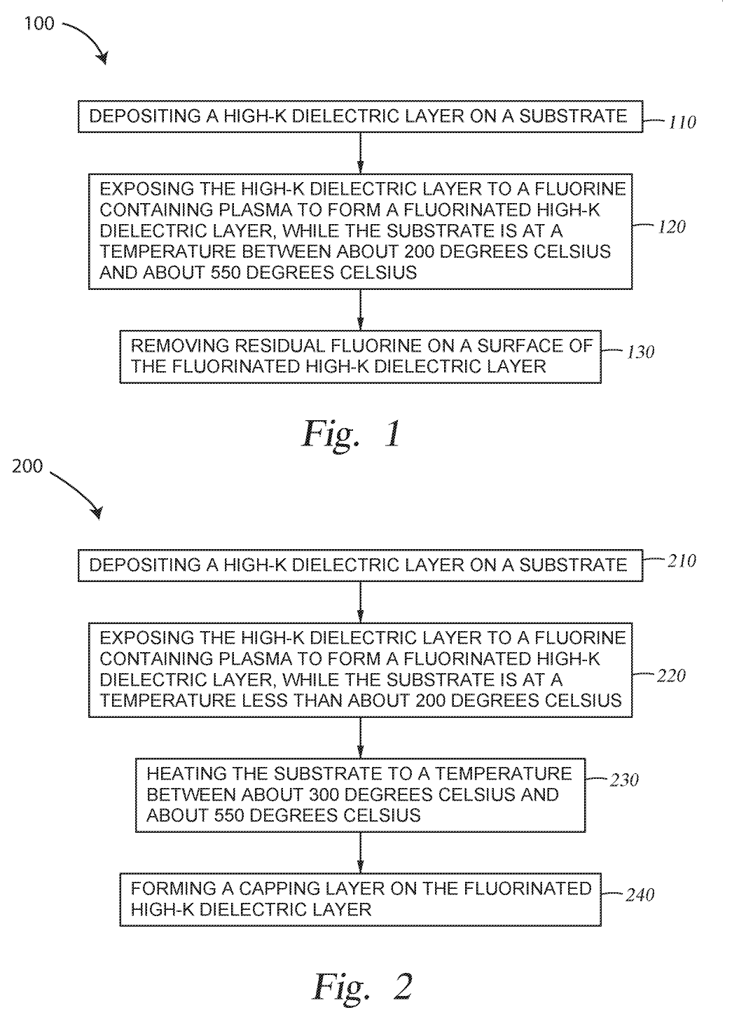

FIG. 1 illustrates operations of a method 100 according to embodiments disclosed herein. At block 110, a high-k dielectric layer is deposited on a substrate. The substrate may be a silicon substrate including an interlayer formed thereon. The interlayer may be a dielectric layer, such as a silicon oxide layer. The high-k dielectric layer may be deposited on the substrate by any suitable deposition techniques such as atomic layer deposition (ALD), chemical vapor deposition (CVD), physical vapor deposition (PVD), thermal and plasma techniques and combinations thereof. At block 120, the deposited high-k dielectric layer is exposed to a fluorine containing plasma to form a fluorinated high-k dielectric layer, while the substrate is at a temperature between about 200 degrees Celsius and about 550 degrees Celsius.

During fluorination of the high-k dielectric layer to form the fluorinated high-k dielectric layer of block 120, the high-k dielectric layer is exposed to fluorine radicals in a processing chamber. The fluorine radicals are formed by energizing a fluorine containing gas. The fluorine containing gas is flowed into a processing chamber, and may be activated by forming a fluorine containing plasma inside of the processing chamber using a plasma source, such as inductively coupled plasma (ICP), capacitively coupled plasma (CCP), or any suitable plasma source. The fluorine containing plasma contains fluorine radicals. The fluorine containing gas may also be activated thermally or in a remote plasma source. The fluorine containing gas may be a carbon-free fluorine containing gas, such as NF₃, F₂, HF, or other suitable fluorine containing gas. The fluorine containing gas may be co-flowed with an inert gas, such as N₂ or argon. In one embodiment, the processing chamber includes an ion filter to prevent fluorine ions from contacting and etching the high-k dielectric layer. In one plasma embodiment, the fluorination process is conducted with a plasma power density setting of less than about 0.28 W/cm² in order to minimize ion energy, which prevents fluorine ions from etching the high-k dielectric layer. When the fluorine radicals are formed in a remote plasma source, the fluorine radicals are flowed into the processing chamber along a conduit that has a length selected. The fluorination process proceeds at a time period from about 10 seconds to about 360 seconds, such as from about 30 seconds to about 180 seconds, for example, about 120 seconds.

The substrate may be supported by a substrate support inside of the processing chamber, and the substrate support includes a heating element in order to heat the substrate to a predetermined temperature. During fluorination of the high-k dielectric layer of block 120, the substrate is heated to a temperature between about 200 degrees Celsius and about 550 degrees Celsius, such as between about 400 degrees Celsius and about 500 degrees Celsius. The fluorine radicals are diffused into the high-k dielectric layer and reach the interface, which is at a low energy state for the fluorine radicals, at a temperature that is greater than about 20 degrees Celsius. However, in order to form fluorine bonds at the interface between the high-k dielectric layer and the substrate, a hydrogen atom at an end of a dangling bond at the interface is removed by thermal energy, which is provided when the temperature of the substrate is heated to over 200 degrees Celsius, such as between about 400 degrees Celsius and about 500 degrees Celsius. Thus, by heating the substrate to a temperature between about 200 degrees Celsius and about 550 degrees Celsius, the fluorine radicals not only reaching the interface but also form fluorine bonds with the dangling bonds at the interface. In addition, at a temperature that is less than about 600 degrees Celsius, the fluorine radicals do not etch any materials. Once fluorine bonds are formed at the interface, etching will not occur at the interface even if subsequent thermal processes can reach a temperature greater than 600 degrees, such as 900 degrees Celsius since fluorine bonds are stable.

At block 130, residual fluorine radicals on the surface of the fluorinated high-k dielectric layer are removed. Because subsequent processes may subject the fluorinated high-k dielectric layer to elevated temperature, such as about 900 degrees Celsius, residual fluorine radicals on the surface of the fluorinated high-k dielectric layer may be removed in order to prevent the etching of the fluorinated high-k dielectric layer. The removal of the residual fluorine radicals may be performed by exposing the fluorinated high-k dielectric layer to an ammonia gas into the process chamber while the temperature of the substrate is between about 100 degrees Celsius and about 500 degrees Celsius, such as between about 400 degrees Celsius and about 500 degrees Celsius. The ammonia gas reacts with the residual fluorine radicals on the surface of the high-k dielectric layer to form a salt, and the salt sublimes at the temperature between about 100 degrees Celsius and about 500 degrees Celsius. During the removal process, the plasma power is turned off in order to prevent nitridating the fluorinated high-k dielectric layer.

In some embodiments, the removal process may be performed by forming a hydrogen containing plasma or hydrogen and oxygen containing plasma in the processing chamber while the temperature of the substrate is between about 20 degrees Celsius and about 500 degrees Celsius, such as between about 400 degrees Celsius and about 500 degrees Celsius. The hydrogen containing plasma or hydrogen and oxygen containing plasma may be formed by flowing a hydrogen containing gas or a hydrogen and oxygen containing gas into the processing chamber and energizing the gas with the plasma power. In some embodiments, the removal process may be performed by flowing a hydrogen containing gas or water vapor into the processing chamber while the plasma power is turned off and the temperature of the substrate is between about 100 degrees Celsius and about 500 degrees Celsius, such as between about 400 degrees Celsius and about 500 degrees Celsius. The removal process of block 130 and the fluorination process of block 120 may be performed in the same process chamber.

Alternatively, the removal process of block 130 is performed by rinsing the fluorinated high-k dielectric layer with deionized (DI) water at a temperature between about 20 degrees Celsius and about 100 degrees Celsius.

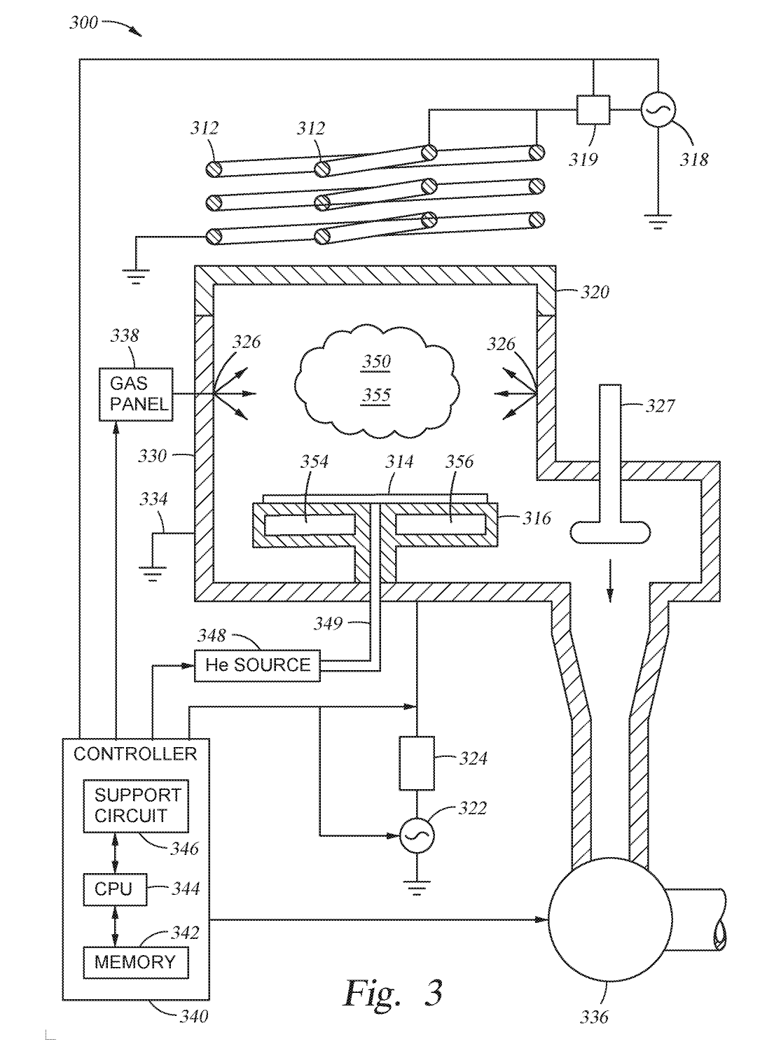

FIG. 2 illustrates operations of a method 200 according to another embodiment disclosed herein. At block 210, a high-k dielectric layer is deposited on a substrate. The operation at block 210 may be the same as the operation at block 110. Next, at block 220, the deposited high-k dielectric layer is exposed to a fluorine containing plasma to form a fluorinated high-k dielectric layer, while the substrate is at a temperature less than about 200 degrees, such as between about 20 degrees Celsius and about 180 degrees Celsius. The fluorine containing plasma may be formed by the same operations described at block 120 and the substrate may be heated by the heating element in the substrate support inside of the processing chamber.

At less than about 200 degrees Celsius, the fluorine radicals are diffused into the high-k dielectric layer to the interface between the high-k dielectric layer and the substrate, which is at a low energy state for the fluorine radicals. However, in order to form fluorine bonds at the interface, a hydrogen atom at an end of a dangling bond at the interface is removed by thermal energy. The thermal energy may be provided by a post fluorination anneal (PFA), which is heating the substrate to a temperature between about 300 degrees Celsius and about 550 degrees Celsius, as shown at block 230. The PFA operation of block 230 and the fluorination of block 220 may be performed in the same processing chamber. During the PFA, the plasma power is turned off and the fluorine containing gas or radicals are stopped from flowing into the processing chamber. The PFA operation proceeds at a time period from about 1 second to about 130 seconds, such as from about 5 seconds to about 120 seconds, for example, about 30 seconds. The PFA operation can also remove some residual fluorine radicals on the surface of the fluorinated high-k dielectric layer. Alternatively, the thermal energy may be provided by increasing the temperature of the substrate to between about 300 degrees Celsius and about 550 degrees Celsius while the plasma power is on.

At block 240, a capping layer is formed on the fluorinated high-k dielectric layer. The capping layer may be any suitable capping layer, such as a titanium nitride layer. The capping layer may be formed by any suitable method, such as ALD. In one embodiment, the capping layer is a titanium nitride layer and is formed by ALD. The ALD operation used to form the titanium nitride layer includes flowing a nitrogen containing gas into the processing chamber, flowing a titanium containing gas into the process chamber, and repeating the alternating flowing of the gases into the processing chamber. In one embodiment, the nitrogen containing gas is ammonia and the substrate is heated to a temperature ranging from about 400 degrees Celsius to about 500 degrees Celsius, such as about 450 degrees Celsius. In this embodiment, the heating the substrate to a temperature between about 300 degrees Celsius and about 550 degrees Celsius described at block 230 may be omitted. During the forming of the capping layer, the substrate may be heated to a temperature that will provide the thermal energy to form fluorine bonds at the interface, and the residual fluorine radicals on the surface of the fluorinated high-k dielectric layer may be removed by the ammonia gas. Thus, after forming the capping layer as shown at block 240, etching by fluorine radicals are minimized during subsequent processes, even if the substrate may be heated to about 900 degrees Celsius. In one embodiment, the removal operation described at block 130 may be performed prior to forming the capping layer as described at block 240.

FIG. 3 is a schematic diagram of a plasma chamber 300 according to one embodiment disclosed herein. The plasma chamber 300 is an ICP chamber that is one example of a processing chamber that may be used to practice one or more operations described herein.

The plasma chamber 300 includes an electrostatic chuck 316 within a conductive body (wall) 330, and a controller 340. The plasma chamber 300 is supplied with a substantially flat dielectric ceiling 320. Other modifications of the plasma chamber 300 may have other types of ceilings, e.g., a dome-shaped ceiling. Above the ceiling 320 is disposed an antenna including at least one inductive coil element 312 (two co-axial elements 312 are shown). The inductive coil element 312 is coupled, through a first matching network 319, to a plasma power source 318. The plasma power source 318 typically is capable of producing up to 3000 W at a tunable frequency in a range, for example, from 50 kHz to 13.56 MHz.

The electrostatic chuck 316 includes a first electrode 354 and a second electrode 356 embedded in a dielectric material. The first electrode 354 and second electrode 356 are biased with DC potentials to provide the chucking action that holds the substrate 314 disposed on the electrostatic chuck 316. The electrostatic chuck 316 may also be a monopolar chuck. The electrostatic chuck 316 is coupled, through a second matching network 324, to a biasing power source 322. The biasing power source 322 is generally capable of producing a RF signal having a tunable frequency of 50 kHz to 13.56 MHz and a power of between 0 and 5000 watts. Optionally, the biasing power source 322 may be a DC or pulsed DC source. A controller 340 including a central processing unit (CPU) 344, a memory 342, and support circuits 346 for the CPU 344 and facilitates control of the components of the plasma chamber 300 and, as such, of the fluorination operation as discussed.

In operation, the substrate 314 is placed on the electrostatic chuck 316 and process gases are supplied from a gas panel 338 through entry ports 326 to form a gaseous mixture 350. The gaseous mixture 350 is energized to form a plasma 355 in the plasma chamber 300 by applying power from the plasma power source 318. The pressure within the interior of the plasma chamber 300 is controlled using a throttle valve 327 and a vacuum pump 336. The chamber wall 330 may be coupled to an electrical ground 334. The temperature of the wall 330 is controlled using liquid-containing conduits (not shown) that run through the wall 330.

The temperature of the substrate 314 is controlled by a resistive heater (not shown) within the electrostatic chuck 316. In one embodiment, helium gas from a gas source 348 is provided via a gas conduit 349 to channels (not shown) formed in the surface of the electrostatic chuck 316 to a fine space (not shown) formed between the reverse surface of the substrate 314 and the upper surface of the electrostatic chuck 316. The helium gas facilitates uniform heating of the substrate 314.

To facilitate control of the plasma chamber 300 as described above, the controller 340 may be one of any form of general-purpose, computer processor that can be used in an industrial setting for controlling various chambers and sub-processors. The memory 342, or computer-readable medium, of the CPU 344 may be one or more of readily available memory such as random access memory (RAM), read only memory (ROM), floppy disk, hard disk, or any other form of digital storage, local or remote. The support circuits 346 are coupled to the CPU 344 for supporting the processor in a conventional manner. These circuits include cache, power supplies, clock circuits, input/output circuitry and subsystems, and the like. The memory 342 may store instructions such as a software routing that, when executed, cause the plasma chamber 300 to perform any of the methods described herein. The software routine may also be stored and/or executed by a second CPU (not shown) that is remotely located from the hardware being controlled by the CPU 344.

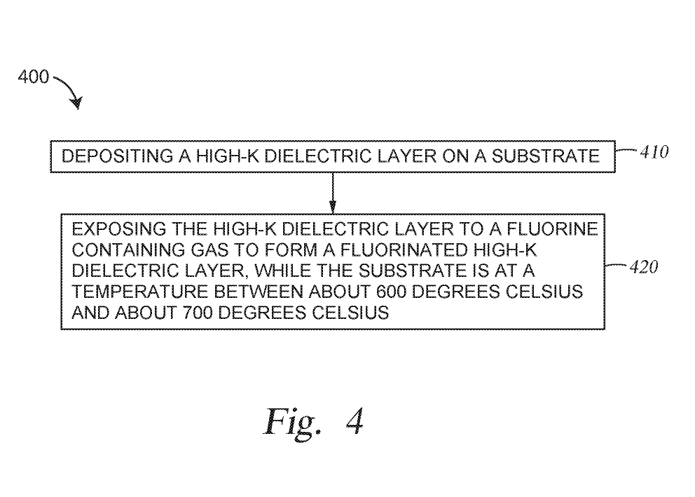

FIG. 4 illustrates operations of a method 400 according to another embodiment disclosed herein. The method 400 starts at block 410, which is depositing a high-k dielectric layer on a substrate. The operation at block 410 may be the same as the operation at block 110. Next, at block 420, the deposited high-k dielectric layer is exposed to a fluorine containing gas to form a fluorinated high-k dielectric layer in a processing chamber. During the fluorination operation, the substrate is at a temperature between about 600 degrees Celsius and about 700 degrees Celsius, such as about 650 degrees Celsius. The fluorine containing gas is introduced into the processing chamber at a temperature less than about 100 degrees Celsius, such as about 20 degrees Celsius.

It has been surprisingly found that even if the substrate is heated to a temperature greater than 600 degrees Celsius, no etching will occur if the fluorine containing gas is introduced into the processing chamber at a temperature less than about 100 degrees Celsius. In other words, the fluorine containing gas, prior to entering the processing chamber, is at a temperature less than about 100 degrees Celsius, such as about 20 degrees Celsius. The fluorine containing gas will produce fluorine radicals at a temperature between about 600 degrees Celsius and about 700 degrees Celsius without being energized by a plasma power. The fluorine radicals are diffused into the high-k dielectric layer to form a fluorinated high-k dielectric layer and may form fluorine bonds at the interface. Removal operation described at block 130 may be performed after forming the fluorinated high-k dielectric layer as described at block 420. Alternatively or in addition to, operations described at block 230 and/or block 240 may be performed after forming the fluorinated high-k dielectric layer as described at block 420.

While the foregoing is directed to embodiments of the present disclosure, other and further embodiments of the disclosure may be devised without departing from the basic scope thereof, and the scope thereof is determined by the claims that follow.

1. A method, comprising:
exposing a substrate having a high-k dielectric layer to a fluorine containing plasma, wherein a temperature of the substrate is maintained between about 200 degrees Celsius and about 550 degrees Celsius during the exposure to the fluorine containing plasma.

2. The method of claim 1, wherein the fluorine containing plasma is formed by energizing a fluorine containing gas.

3. The method of claim 2, wherein the fluorine containing gas is carbon-free.

4. The method of claim 2, wherein the fluorine containing gas comprises NF₃, F₂, or HF.

5. The method of claim 1, further comprising forming a fluorinated high-k dielectric layer.

6. The method of claim 5, further comprising exposing the fluorinated high-k dielectric layer to a gas or plasma while the temperature of the substrate is between about 100 degrees Celsius and about 500 degrees Celsius.

7. The method of claim 6, wherein the gas or plasma comprises ammonia gas, a hydrogen containing gas, a hydrogen containing plasma, water vapor, or a hydrogen and oxygen containing plasma.

8. The method of claim 1, further comprising forming a capping layer on the fluorinated high-k dielectric layer.

9. A method, comprising:
forming a fluorinated high-k dielectric layer by fluorinating a high-k dielectric layer on a substrate, wherein the fluorinating the high-k dielectric layer comprises:
exposing the high-k dielectric layer to a fluorine containing plasma at a first temperature less than about 200 degrees Celsius; and
increasing the first temperature to a second temperature between about 300 degrees Celsius and about 550 degrees Celsius.

10. The method of claim 9, wherein the increasing the first temperature to the second temperature is a result of a post fluorination anneal process, wherein during the post fluorine anneal process a plasma power is turned off.

11. The method of claim 9, wherein the fluorine containing plasma is formed by energizing a fluorine containing gas.

12. The method of claim 11, wherein the fluorine containing gas is carbon-free.

13. The method of claim 11, wherein the fluorine containing gas comprises NF₃, F₂, or HF.

14. The method of claim 9, further comprising exposing the fluorinated high-k dielectric layer to a gas or plasma while the temperature of the substrate is between about 100 degrees Celsius and about 500 degrees Celsius.

15. The method of claim 14, wherein the gas or plasma comprises ammonia gas, a hydrogen containing gas, a hydrogen containing plasma, water vapor, or a hydrogen and oxygen containing plasma.

16. The method of claim 9, further comprising forming a capping layer on the fluorinated high-k dielectric layer.

17. The method of claim 16, wherein the capping layer is formed at a temperature between about 400 degrees Celsius and about 500 degrees Celsius.

18. A method, comprising:
forming a fluorinated high-k dielectric layer by fluorinating a high-k dielectric layer on a substrate, wherein the fluorinating the high-k dielectric layer comprises exposing the high-k dielectric layer to a fluorine containing gas, wherein a temperature of the substrate is between about 650 degrees Celsius and about 700 degrees Celsius during the exposure to the fluorine containing gas, wherein the fluorine containing gas is introduced into the processing chamber at a temperature less than about 100 degrees Celsius.

19. The method of claim 18, further comprising forming a capping layer on the fluorinated high-k dielectric layer.

20. The method of claim 19, wherein the capping layer is formed at a temperature between about 400 degrees Celsius and about 500 degrees Celsius.
